(19) United States
(12) Patent Application Publication
(10) Pub. No.: US 2013/0074329 A1
(43) Pub. Date: Mar. 28, 2013

(54) MOUNTING APPARATUS, ELECTRONIC COMPONENT MOUNTING METHOD, SUBSTRATE PRODUCTION METHOD, AND PROGRAM

(71) Applicant: Togo Matsuura, Saitama (JP)

(72) Inventor: Togo Matsuura, Saitama (JP)

(73) Assignee: SONY CORPORATION, Tokyo (JP)

(21) Appl. No.: 13/609,392

(22) Filed: Sep. 11, 2012

(30) Foreign Application Priority Data
Sep. 27, 2011 (JP) 2011-210935

(51) Int. Cl. H05K 3/30

(52) U.S. Cl. 29/832; 29/705

(57) ABSTRACT

A mounting apparatus includes a holding unit, a sensor unit, and a controller. The holding unit is configured to hold an electronic component, move toward a substrate while holding the electronic component, and mount the electronic component on the substrate. The sensor unit is configured to detect an oscillation of the holding unit. The controller is configured to judge, based on information on the oscillation detected by the sensor unit, timings at which a position of the electronic component held by the oscillating holding unit overlaps a mounting position on the substrate, and control a movement of the holding unit toward the substrate such that the electronic component is mounted on the substrate at any of the judged timings.

### BACKGROUND

The present disclosure relates to a technique used in a mounting apparatus that mounts electronic components on a substrate, and the like.

From the past, there has been known a mounting apparatus including a conveyance unit that conveys a substrate and positions it at a predetermined position, a supply unit that supplies electronic components, a head having a sucking nozzle capable of holding and releasing the electronic components, and a drive mechanism that drives the head.

In such a mounting apparatus, the head is first moved to a position above the supply unit by the drive mechanism. Then, the sucking nozzle is lowered so that the electronic components are sucked and held by the sucking nozzle, and the sucking nozzle holding the electronic components is raised after that. When the head includes a plurality of sucking nozzles, each of the plurality of sucking nozzles sucks and holds the electronic components. Subsequently, the head (sucking nozzle) is moved to a mounting position on the substrate by the drive mechanism, and the sucking nozzle is lowered above the substrate so that the electronic components are mounted on the substrate. When the head includes a plurality of sucking nozzles, the head is moved to a next mounting position on the substrate, and the sucking nozzle is lowered at that position so that the electronic components are mounted on the substrate.

In such a mounting apparatus, the head (sucking nozzle) oscillates when it is moved from the supply unit to a position above the substrate and stops or when it is moved to the next mounting position on the substrate and stops. Since the head (sucking nozzle) oscillates when it stops as described above, when the sucking nozzle is lowered without taking any countermeasure, there is a problem that the electronic components cannot be mounted accurately at the mounting position on the substrate.

As a technique related to such a problem, Japanese Patent Application Laid-open No. 2010-67704 (hereinafter, referred to as Patent Document 1) discloses a technique for controlling, in a case where a head is moved from a supply unit to a position on a substrate, an oscillation caused in the head by controlling a movement of the head.

### SUMMARY

The technique disclosed in Patent Document 1, however, has a problem that a movement time that the head takes to move to a position above the substrate becomes longer as a frequency of the oscillation of the head (sucking nozzle) as an oscillation suppression target becomes larger. In this case, since it takes time to move, there is a problem that a productivity of a substrate is lowered.

In view of the circumstances as described above, there is a need for a technique with which highly-accurate mounting of electronic components and an improvement of a productivity of a substrate can be realized.

According to an embodiment of the present disclosure, there is provided a mounting apparatus including a holding unit, a sensor unit, and a controller.

The holding unit is configured to hold an electronic component, move toward a substrate while holding the electronic component, and mount the electronic component on the substrate.

The sensor unit is configured to detect an oscillation of the holding unit.

The controller is configured to judge, based on information on the oscillation detected by the sensor unit, timings at which a position of the electronic component held by the oscillating holding unit overlaps a mounting position on the substrate, and control a movement of the holding unit toward the substrate such that the electronic component is mounted on the substrate at any of the judged timings.

In such a mounting apparatus, the electronic component can be mounted on the substrate at the timing at which the position of the electronic component held by the oscillating holding unit overlaps the mounting position on the substrate. Therefore, even when the holding unit holding the electronic component is oscillating, the holding unit can be moved toward the substrate so that the electronic component can be accurately mounted on the substrate. In addition, since the oscillation is of no problem in such a mounting apparatus, a movement speed of the holding unit when it moves from the supply unit to a position on the substrate can be raised, for example. Therefore, the productivity of a substrate can be improved. In other words, in such a mounting apparatus, highly-accurate mounting of the electronic components and an improvement of the productivity of a substrate can both be realized.

In the mounting apparatus, the controller may calculate a movement start time as a time the holding unit starts moving toward the substrate based on the timings at which the position of the electronic component held by the oscillating holding unit overlaps the mounting position on the substrate and a movement time as a time up to a time the holding unit mounts the electronic component on the substrate since starting to move toward the substrate.

With this structure, the movement start time of the holding unit can be calculated appropriately.

In the mounting apparatus, the controller may measure, based on the information on the oscillation, a cycle of the timings at which the position of the electronic component held by the oscillating holding unit overlaps the mounting position on the substrate, and predict the timings at which the position of the electronic component held by the oscillating holding unit overlaps the mounting position on the substrate based on the measured cycle.

In the mounting apparatus, the controller may predict a timing at which the position of the electronic component held by the oscillating holding unit overlaps the mounting position on the substrate by adding the cycle to a time of any of the timings at which the position of the electronic component held by the oscillating holding unit overlaps the mounting position on the substrate, and calculate a time obtained by subtracting the movement time from the predicted time as the movement start time.

With this structure, the movement start time of the holding unit can be calculated appropriately.

In the mounting apparatus, the controller may predict, by obtaining n using the following expression and adding n times the cycle to a time of any of the timings at which the position of the electronic component held by the oscillating holding unit overlaps the mounting position on the substrate, the timing at which the position of the electronic component held by the oscillating holding unit overlaps the mounting position on the substrate, and calculate a time obtained by subtracting the movement time from the predicted time as the movement start time.

n−1T<P≦nT

(where T represents the cycle, P represents the movement time, and n represents an integer of 1 or more)

With this structure, even when the cycle is larger than the movement time that the holding unit takes to move toward the substrate, the movement start time of the holding unit can be calculated appropriately.

In the mounting apparatus, the controller may measure the cycle based on the information on the oscillation for each of timings at which the holding unit moves toward the substrate and mounts the electronic component.

In such a mounting apparatus, the cycle is measured for each of the timings at which the holding unit mounts the electronic component. Therefore, when the oscillation cycle of the holding unit varies depending on a parameter such as a movement distance at a time the holding unit moves from the supply unit to a position on the substrate, the timing can be judged by appropriately calculating the cycle. As a result, mounting accuracy of the electronic components can be additionally improved.

The mounting apparatus may further include a storage. In this case, the controller may measure, before the holding unit mounts the electronic component, the cycle based on the information on the oscillation and store the measured cycle in the storage in advance.

In such a mounting apparatus, since the cycle is measured in advance based on the information on the oscillation of the holding unit, the cycle does not need to be measured at a timing at which the holding unit mounts the electronic component. Therefore, when moving the holding unit to the mounting position on the substrate, the holding unit can be readily moved toward the substrate. As a result, the productivity of a substrate can be additionally improved.

In the mounting apparatus, the sensor unit may include a first sensor that detects an oscillation in a first direction as a direction orthogonal to a direction in which the holding unit moves toward the substrate. In addition, in the mounting apparatus, the sensor unit may further include a second sensor that detects an oscillation in a second direction that is orthogonal to a direction in which the holding unit moves toward the substrate and is different from the first direction.

Since the oscillation of the holding unit can be detected accurately when the sensor unit includes the first sensor and the second sensor, the mounting accuracy of the electronic components can be additionally improved.

According to an embodiment of the present disclosure, there is provided an electronic component mounting method including detecting an oscillation of a holding unit that holds an electronic component, moves toward a substrate while holding the electronic component, and mounts the electronic component on the substrate.

Based on information on the detected oscillation, timings at which a position of the electronic component held by the oscillating holding unit overlaps a mounting position on the substrate are judged.

A movement of the holding unit toward the substrate is controlled such that the electronic component is mounted on the substrate at any of the judged timings, to mount the electronic component on the substrate.

According to an embodiment of the present disclosure, there is provided a substrate production method including detecting an oscillation of a holding unit that holds an electronic component, moves toward a substrate while holding the electronic component, and mounts the electronic component on the substrate.

Based on information on the detected oscillation, timings at which a position of the electronic component held by the oscillating holding unit overlaps a mounting position on the substrate are judged.

A movement of the holding unit toward the substrate is controlled such that the electronic component is mounted on the substrate at any of the judged timings, to produce the substrate on which the electronic component is mounted.

According to an embodiment of the present disclosure, there is provided a program that causes a mounting apparatus to execute the steps of:

detecting an oscillation of a holding unit that holds an electronic component, moves toward a substrate while holding the electronic component, and mounts the electronic component on the substrate;

judging, based on information on the detected oscillation, timings at which a position of the electronic component held by the oscillating holding unit overlaps a mounting position on the substrate; and

controlling a movement of the holding unit toward the substrate such that the electronic component is mounted on the substrate at any of the judged timings.

As described above, according to the embodiments of the present disclosure, a technique with which highly-accurate mounting of electronic components and an improvement of a productivity of a substrate can both be realized can be provided.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a front view of a mounting apparatus according to an embodiment of the present disclosure;

FIG. 2 is a plan view of the mounting apparatus;

FIG. 3 is a block diagram showing an electrical structure of the mounting apparatus;

FIG. 4 is a flowchart showing an operation of the mounting apparatus;

FIG. 5 is a timing chart showing a relationship between an acceleration obtained by an acceleration sensor and a lowering timing of a sucking nozzle;

FIG. 6 is a flowchart showing an operation of the mounting apparatus according to another embodiment of the present disclosure; and

FIG. 7 is a timing chart showing a relationship between an acceleration obtained by the acceleration sensor and a lowering timing of the sucking nozzle.

### DETAILED DESCRIPTION OF EMBODIMENTS

Hereinafter, embodiments of the present disclosure will be described with reference to the drawings.

### First Embodiment

[Structure of Mounting Apparatus and Structures of Respective Units]

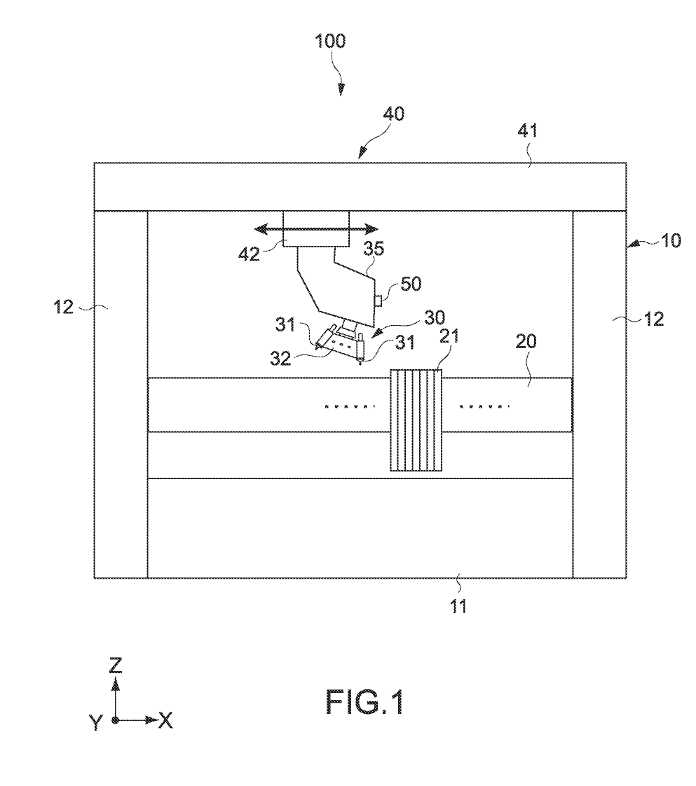

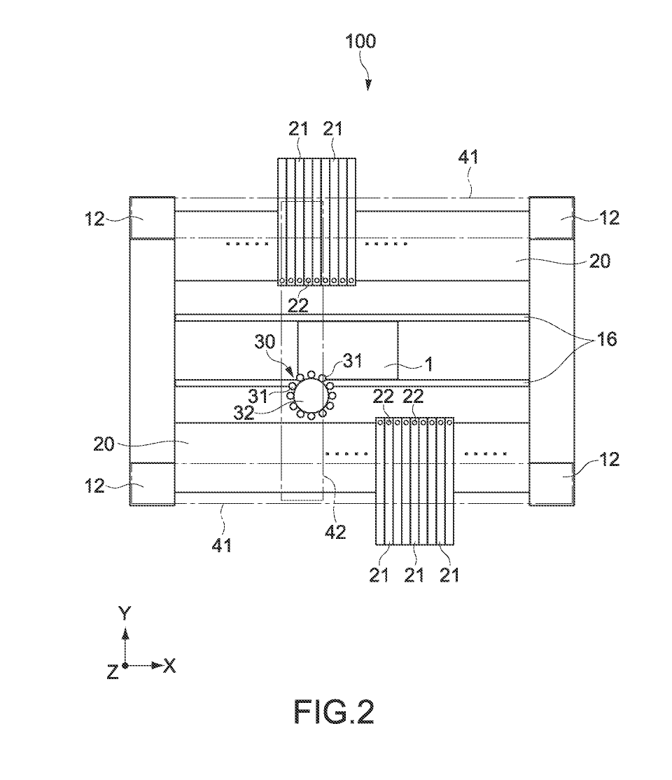

FIG. 1 is a front view of a mounting apparatus 100 according to an embodiment of the present disclosure. FIG. 2 is a plan view of the mounting apparatus 100.

As shown in FIGS. 1 and 2, the mounting apparatus 100 includes a frame 10, a conveyor 16 that conveys a substrate 1, and supply units 20 that are respectively provided on both sides of the conveyor 16 and supply electronic components (not shown). The mounting apparatus 100 also includes a mounting head 30 including sucking nozzles 31 (holding unit) that each suck an electronic component supplied from the supply units 20 and mount it on the substrate 1, and a drive mechanism 40 that drives the mounting head 30. The mounting apparatus 100 also includes a sensor unit 50 that detects an oscillation of the sucking nozzles 31.

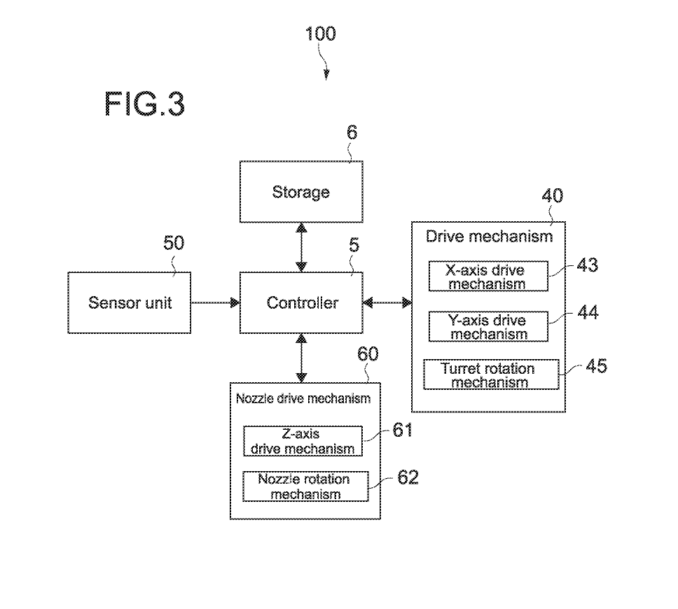

FIG. 3 is a block diagram showing an electrical structure of the mounting apparatus 100.

As shown in FIG. 3, the mounting apparatus 100 includes a controller 5 such as a CPU (Central Processing Unit) that collectively controls the respective units of the mounting apparatus 100. The mounting apparatus 100 also includes a storage 6 including a nonvolatile memory that stores various programs requisite for control of the controller 5 and a volatile memory that is used as a working area of the controller 5. The mounting apparatus 100 also includes a nozzle drive mechanism 60 that drives the sucking nozzles 31. It should be noted that although illustrations are omitted in FIG. 3, the controller 5 is also electrically connected to the conveyor 16, the supply units 20, and the like.

In descriptions below, the structure of the mounting apparatus 100 will be described in detail while mainly referring to FIGS. 1 and 2 and referring to FIG. 3 as appropriate.

The conveyor 16 extends along an X-axis direction and conveys the substrate 1 handed over from another apparatus provided on an upstream side of the mounting apparatus 100 to a predetermined position. Further, after electronic components are mounted on the substrate 1, the conveyor 16 conveys the substrate 1 and hands it over to another apparatus provided downstream.

A plurality of tape feeders 21 are arranged in each of the supply units 20 along the X-axis direction. The tape feeders 21 each include a reel around which a carrier tape accommodating electronic components inside is wound and a feed mechanism that feeds the carrier tape in step feed. Inside the carrier tape, electronic components such as a resistor, a capacitor, and a coil are accommodated for each type. A supply window 22 is formed on an upper surface at an end portion of a cassette of each of the tape feeders 21, and the electronic components are supplied via the supply window 22.

The frame 10 includes a base 11 provided at a bottom portion thereof and a plurality of support columns 12 fixed to the base 11.

The drive mechanism 40 includes two X beams 41 provided across an upper portion of the plurality of support columns 12 in the X-axis direction and a Y beam 42 bridged between the two X beams 41 in a Y-axis direction. It should be noted that in FIG. 2, the X beam 41 on the front side and the Y beam 42 are illustrated in dashed lines to help understand the figure.

The Y beam 42 is attached to lower sides of the two X beams 41 such that the Y beam 42 is movable with respect to the X beams 41 in the X-axis direction. The X beams 41 have an X-axis drive mechanism 43 (see FIG. 3) for moving the Y beam 42 in the X-axis direction inside, and by driving the X-axis drive mechanism 43, the Y beam 42 is moved in the X-axis direction below the X beams 41.

Below the Y beam 42, a carriage 35 that holds the mounting head 30 is attached. The carriage 35 is attached while being movable with respect to the Y beam 42 in the Y-axis direction. The Y beam 42 has a Y-axis drive mechanism 44 (see FIG. 3) for moving the carriage 35 in the Y-axis direction inside, and by driving the Y-axis drive mechanism 44, the carriage 35 is moved in the Y-axis direction below the Y beam 42.

By driving the X-axis drive mechanism 43 and the Y-axis drive mechanism 44, the mounting head 30 (sucking nozzles 31) provided below the carriage 35 is moved in the X- and Y-axis directions. Examples of the X-axis drive mechanism 43 and the Y-axis drive mechanism 44 include a ball screw drive mechanism, a belt drive mechanism, and a linear motor drive mechanism.

The mounting head 30 includes a turret 32 rotatably attached to the carriage 35 and the plurality of sucking nozzles 31 attached to the turret 32 at regular intervals along a circumferential direction of the turret 32.

The turret 32 is rotatable using an oblique axis as a center axis for rotations. By driving a turret rotation mechanism 45 (see FIG. 3) of the drive mechanism 40, the turret 32 rotates about the axis as the center axis.

The sucking nozzles 31 are attached to the turret 32 such that axis lines of the sucking nozzles 31 tilt with respect to the rotation axis of the turret 32.

The sucking nozzles 31 are each movably supported by the turret 32 along the axis-line direction. The sucking nozzles 31 are also rotatably supported by the turret 32. By driving a Z-axis drive mechanism 61 (see FIG. 3) of the nozzle drive mechanism 60, the sucking nozzles 31 move in the axis-line direction at a predetermined timing. Also by driving a nozzle rotation mechanism 62 (see FIG. 3), the sucking nozzles 31 rotate about the axis lines at a predetermined timing.

The sucking nozzles 31 are connected to an air compressor (not shown). The sucking nozzles 31 are capable of sucking and releasing the electronic components according to a switch between negative and positive pressures of the air compressor.

An axis line of a lowest sucking nozzle 31 among the plurality of sucking nozzles 31 (sucking nozzle 31 at rightmost position in FIGS. 1 and 2) is set in a vertical direction. In descriptions below, the position of the sucking nozzle 31 whose axis line is thus set in the vertical direction will be referred to as operation position. The sucking nozzle 31 at the operation position is sequentially switched by a rotation of the turret 32. Among the plurality of sucking nozzles 31, the sucking nozzle 31 at the operation position is moved vertically, or negative and positive pressures are switched therefor.

The sensor unit 50 detects a lateral (direction orthogonal to direction in which sucking nozzle 31 moves toward substrate 1) oscillation of the sucking nozzle 31 at the operation position. In the example shown in FIG. 1, the sensor unit 50 is provided on the carriage 35. The sensor unit 50 is typically provided at a position that oscillates laterally at the same timing as the sucking nozzle 31 at the operation position. Therefore, the sensor unit 50 may be provided at any position as long as it is a position that oscillates at the same timing as the sucking nozzle 31 at the operation position, and may be provided on, for example, the X beams 41 or the Y beam 42.

As the sensor unit 50, an acceleration sensor, a velocity sensor, a displacement sensor, or a combination of two or more sensors described above may be used. The sensor unit 50 may include a first sensor that detects a lateral oscillation in a first direction (e.g., X-axis direction) and a second sensor that detects an oscillation in a second direction (e.g., Y-axis direction) different from the first direction. In this case, the oscillation of the sucking nozzle 31 at the operation position can be measured accurately.

It should be noted that in this embodiment, descriptions will be given assuming that the sensor unit 50 is an acceleration sensor 50 that detects an acceleration in the X-axis direction.

The mounting apparatus 100 includes an image pickup unit (not shown). The image pickup unit includes an image pickup device such as a CCD (Charge Coupled Device) and a CMOS (Complementary Metal Oxide Semiconductor), and such an image pickup device picks up an image of the sucking nozzle 31 holding an electronic component. The image pickup unit is provided so as to move integrally with the mounting head 30, for example, and picks up an image of the nozzle holding an electronic component via an optical system (not shown) such as a mirror.

An image taken by the image pickup unit is subjected to image processing by the controller 5, and a sucking state of an electronic component is judged thereby. After the sucking state is judged, a rotation amount of the sucking nozzle 31 during mounting, or the like is corrected based on the judged sucking state.

[Explanation of Operation]

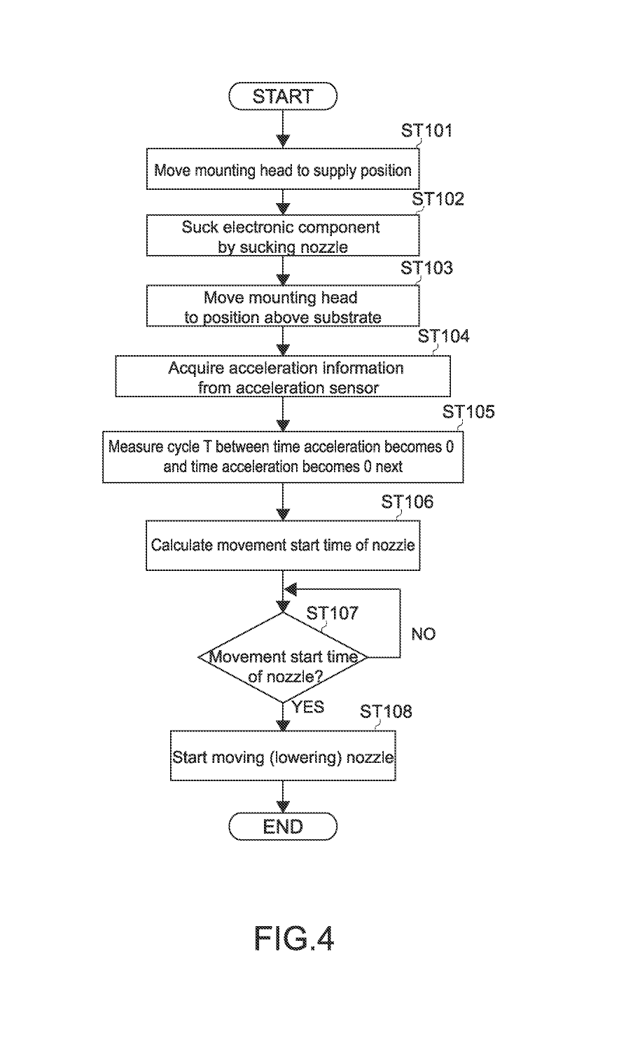

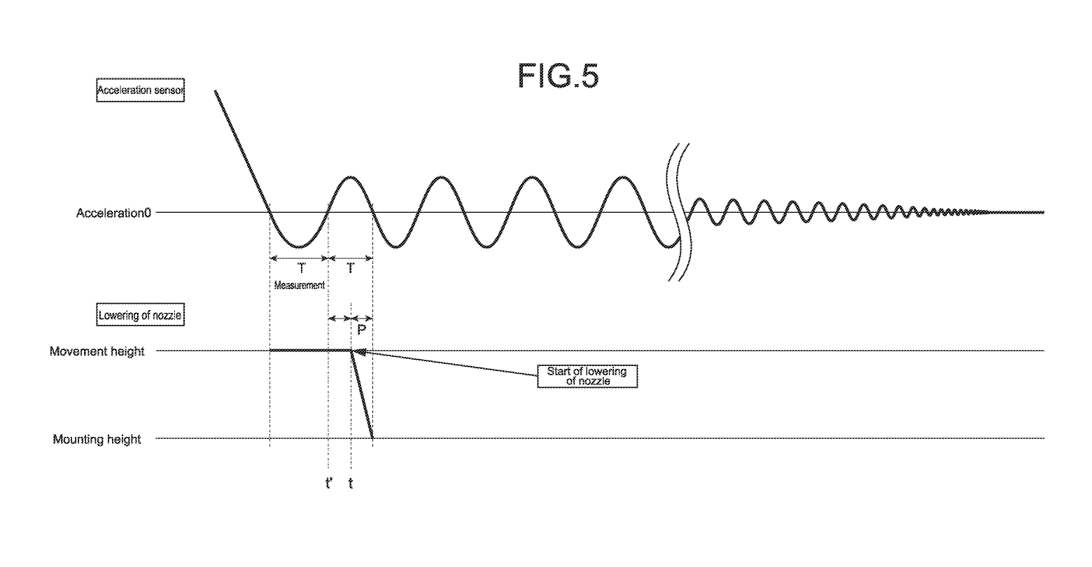

Next, an operation of the mounting apparatus 100 of this embodiment will be described. FIG. 4 is a flowchart showing the operation of the mounting apparatus 100. FIG. 5 is a timing chart showing a relationship between an acceleration obtained by the acceleration sensor 50 and a lowering timing of the sucking nozzle 31.

First, the controller 5 conveys the substrate 1 by the conveyor 16 and positions the substrate 1 at a predetermined position. Next, the controller 5 drives the X-axis drive mechanism 43 and Y-axis drive mechanism 44 of the drive mechanism 40 to move the mounting head 30 (sucking nozzles 31) in the X- and Y-axis directions, and moves the mounting head 30 to an electronic component supply position (position of supply window 22) (Step 101). Then, the controller 5 moves the sucking nozzle 31 at the operation position to a position of the supply window 22 of the tape feeder 21 accommodating a target electronic component.

Subsequently, the controller 5 drives the Z-axis drive mechanism 61 to lower the sucking nozzle 31 at the operation position, and switches the sucking nozzle 31 to a negative pressure by the air compressor. As a result, the electronic component is sucked by a tip end portion of the sucking nozzle 31 (Step 102). After the electronic component is sucked by the sucking nozzle 31, the controller 5 raises the sucking nozzle 31.

Next, the controller 5 drives the turret rotation mechanism 45 to rotate the turret 32 and switches the sucking nozzle 31 at the operation position. Upon switching the sucking nozzle 31 at the operation position, the controller 5 drives the Z-axis drive mechanism 61 to lower the sucking nozzle 31 so that an electronic component is sucked by a tip end of the sucking nozzle 31. As described above, electronic components are sucked by the plurality of sucking nozzles 31.

After the electronic components are sucked by the sucking nozzles 31, the controller 5 drives the X-axis drive mechanism 43 and the Y-axis drive mechanism 44 to move the mounting head 30 (sucking nozzles 31) from the supply position to a position on the substrate 1 (Step 103). Then, the controller 5 positions the electronic component held by the sucking nozzle 31 at the operation position at a mounting position thereof on the substrate 1. By the completion of the positioning, the movement of the mounting head 30 (sucking nozzles 31) in the X- and Y-axis directions stops. At this time, the sucking nozzles 31 oscillate due to an impact caused when the movement stops.

After the electronic component held by the sucking nozzle 31 is positioned at the mounting position thereof on the substrate 1, the controller 5 next acquires information on an acceleration (information on oscillation) from the acceleration sensor 50. A timing at which the acceleration information is acquired is not limited to a timing after the positioning and may be a timing that is a predetermined time before the completion of the positioning. In other words, the acceleration information may be acquired when the sucking nozzle 31 moves a predetermined range from the mounting position on the substrate 1.

FIG. 5 shows an example of the information on an acceleration (X-axis direction) acquired by the acceleration sensor 50. Here, referring to FIG. 5, a basic idea of the present disclosure will be described.

The acceleration (X-axis direction) acquired by the acceleration sensor 50 represents an oscillation of the sucking nozzle 31 at the operation position. Further, a timing at which the acceleration becomes 0 coincides with a timing at which the position of the electronic component held by the sucking nozzle 31 at the operation position overlaps the mounting position on the substrate 1 at which the electronic component is to be mounted.

Therefore, the timing at which the position of the electronic component held by the sucking nozzle 31 overlaps the mounting position on the substrate 1 comes every cycle T corresponding to half the oscillation cycle. It should be noted that although the oscillation of the sucking nozzle 31 is a damped oscillation, the oscillation cycle of the sucking nozzle 31 does not fluctuate drastically. Therefore, for several seconds after the completion of the positioning, it can be assumed that the timing at which the position of the electronic component held by the sucking nozzle 31 overlaps the mounting position on the substrate 1 comes every cycle T.

A movement time P as a time from a start of the movement of the sucking nozzle 31 toward the substrate 1 to mounting of an electronic component on the substrate 1 is assumed to be known. In this case, if the sucking nozzle 31 is started to move at a timing that goes back a time corresponding to the movement time P from the timing at which the acceleration becomes 0, the electronic component can be mounted on the substrate 1 at the timing at which the acceleration becomes 0 (timing at which position of electronic component held by sucking nozzle 31 overlaps mounting position on substrate 1).

Since the timing at which the acceleration becomes 0 (timing at which position of electronic component held by sucking nozzle 31 overlaps mounting position on substrate 1) comes every cycle T, such a timing can be predicted as long as the cycle T is known. In other words, times obtained by adding T, 2T, 3T, . . . to any of the timings at which the acceleration becomes 0 become times at which the acceleration becomes 0 (position of electronic component held by sucking nozzle 31 overlaps mounting position on substrate 1).

Therefore, the cycle T (or 2T, 3T, . . . ) is first added to a time of any of the timings at which the acceleration becomes 0, and a time at which the acceleration becomes 0 next (or after that) is predicted. Then, the movement of the sucking nozzle 31 toward the substrate 1 only needs to be started at a time obtained by subtracting the movement time P from the predicted time of the timing at which the acceleration becomes 0. As a result, the electronic component can be mounted on the substrate 1 at the timing at which the position of the electronic component held by the sucking nozzle 31 at the operation position overlaps the mounting position on the substrate 1 at which the electronic component is to be mounted.

Heretofore, the basic idea of the present disclosure has been described. Now, descriptions will return to the processing of the controller 5.

Upon acquiring the acceleration information from the acceleration sensor 50, the controller 5 measures the cycle T between a time the acceleration has become 0 to a time the acceleration becomes 0 next based on the acceleration information (Step 105). In other words, the controller 5 measures the cycle T of the timing at which the position of the electronic component held by the sucking nozzle 31 overlaps the mounting position on the substrate 1 based on the acceleration information.

The measurement of the cycle T is executed with a completion of the positioning of the electronic component held by the sucking nozzle at the mounting position on the substrate 1 (completion of movement in X- and Y-axis directions) being a trigger.

Next, the controller 5 calculates a movement start time t as a time the sucking nozzle 31 starts moving toward the substrate 1 (Step 106). The movement start time t can be obtained by Expression (1) below.

t=t′+T−P (1)

It should be noted that t′ in Expression (1) represents a time of any of the timings at which the acceleration becomes 0 (timings known from acceleration information from sensor). Specifically, in calculating the movement start time t, a time at which the acceleration becomes 0 next is predicted by first adding the cycle T to the time t′ of any of the timings at which the acceleration becomes 0. Then, a time obtained by subtracting the movement time P from the predicted time of the timing at which the acceleration becomes 0 is calculated, and the calculated time is used as the movement start time t. It should be noted that the movement time P is stored in the storage 6 in advance.

In the example shown in FIG. 5, the time t′ is a time at which the acceleration becomes 0 for the second time since the completion of the positioning. In other words, in the example shown in FIG. 5, the time t′ is a time at which the acceleration becomes 0 right after the cycle T is measured. By thus setting the time t′ to be the time at which the acceleration becomes 0 right after the cycle T is measured, the electronic component mounting speed can be raised. It should be noted that the time t′ is not limited to such a time and may be a time at which the acceleration becomes 0 for the third time or subsequent times since the completion of the positioning.

A case where the cycle T by which the acceleration becomes 0 is larger than the movement time P is also assumed. In a case where the cycle T is assumed to be larger than the movement time P, the controller 5 first obtains n by Expression (2) below.

n−1T<P≦nT (2)

(where n is an integer of 1 or more)

Then, the controller 5 calculates the movement start time t by Expression (3) below.

t=t′+nT−P (3)

Specifically, when the cycle T is assumed to be larger than the movement time P, the controller 5 predicts, after obtaining n using Expression (2) above, a time at which the acceleration becomes 0 by adding n times the cycle T to the time t′ of any of the timings at which the acceleration becomes 0. Then, a time obtained by subtracting the movement time P from the predicted time of the timing at which the acceleration becomes 0 is calculated, and the calculated time is used as the movement start time t.

Upon calculating the movement start time t, the controller 5 next judges whether the current time is the movement start time t of the sucking nozzle (Step 107). When the current time is the movement start time t of the sucking nozzle (YES in Step 107), the controller 5 drives the Z-axis drive mechanism 61 of the nozzle drive mechanism 60 and starts moving (lowering) the sucking nozzle 31 at the operation position (Step 108).

Then, after lowering the sucking nozzle 31 a predetermined distance, the controller 5 stops driving the Z-axis drive mechanism 61 to thus stop lowering the nozzle. Subsequently, the controller 5 switches the pressure of the sucking nozzle 31 from a negative pressure to a positive pressure to mount the electronic component on the substrate 1. After the electronic component is sucked by the sucking nozzle 31, the controller 5 raises the sucking nozzle 31.

By the processing as described above, the electronic component can be mounted on the substrate 1 at the timing at which the position of the electronic component held by the sucking nozzle 31 at the operation position overlaps the mounting position on the substrate 1 at which the electronic component is to be mounted. Therefore, even when the sucking nozzle 31 holding the electronic component is oscillating, the sucking nozzle 31 can be moved toward the substrate 1 so that the electronic component can be mounted accurately on the substrate 1.

Furthermore, since the oscillation is of no problem in the mounting apparatus 100, the movement speed for moving the sucking nozzle 31 from the supply position above the supply units 20 to the a position on the substrate 1 can be raised, for example. Therefore, the productivity of the substrate 1 can be improved. In other words, highly-accurate mounting of electronic components and an improvement of the productivity of the substrate 1 can both be realized.

In the example used herein, the acceleration sensor 50 has been used as the sensor unit 50. However, the same effect can be obtained also when other sensors such as a velocity sensor and a displacement sensor are used as the sensor unit 50.

For simply improving mounting accuracy of electronic components, there is also a method of lowering the sucking nozzle 31 after waiting for the oscillation of the sucking nozzle 31 to attenuate above the substrate 1. In this case, however, since there is a need to wait for the oscillation of the sucking nozzle 31 to attenuate, the productivity of the substrate 1 cannot be improved.

Here, using specific values possible for parameters such as an oscillation frequency of the sucking nozzle 31 and the movement time P of the sucking nozzle 31, with how high an accuracy the electronic component can be actually mounted on the substrate 1 will be described.

The specific parameters possible are as follows.

Oscillation frequency of sucking nozzle 31 at operation position . . . 15 Hz

Oscillation cycle of sucking nozzle 31 . . . About 66 (ms)

Cycle T by which acceleration becomes 0 . . . About 33 (ms) (half the cycle of oscillation of sucking nozzle 31)

Oscillation amplitude of sucking nozzle 31 . . . ±50 (μm)

Nozzle movement time P . . . 14 (ms) (variance: 0.5 (ms))

Movement start time t . . . Time that 19 (ms) has elapsed since time t′

In this example, the oscillation amplitude of the sucking nozzle 31 is ±50 (μm), and there is a variance of 0.5 (ms) for the movement time P of the sucking nozzle 31. Even in such a case, however, a deviation amount of the electronic component from the mounting position on the substrate 1 can be suppressed to be within ±3 (ms) when the electronic component is mounted on the substrate 1.

Next, processing carried out when an electronic component held by the sucking nozzle 31 is mounted on the substrate 1 after the sucking nozzle 31 at the operation position is switched will be described.

Upon completing mounting of the electronic component sucked and held by the sucking nozzle 31 on the substrate 1, the controller 5 drives the turret rotation mechanism 45 to rotate the turret 32 and switch the sucking nozzle 31 at the operation position. Upon switching the sucking nozzle 31 at the operation position, the controller 5 drives the X-axis drive mechanism 43 and the Y-axis drive mechanism 44 to position the electronic component held by the sucking nozzle 31 at the operation position at the mounting position on the substrate 1 at which the electronic component is to be mounted.

Also in such a case, the sucking nozzle 31 oscillates. Therefore, also in such a case in this embodiment, the processing of Steps 104 to 108 is executed. Specifically, the controller 5 measures the cycle T by which the acceleration becomes 0 for each timing at which the sucking nozzle 31 moves toward the substrate 1 and mounts the electronic component based on the acceleration information and judges the timing at which the position of the electronic component held by the sucking nozzle 31 overlaps the mounting position on the substrate 1.

For example, the oscillation cycle (cycle T by which acceleration becomes 0) of the sucking nozzle 31 may vary depending on parameters such as a position of the mounting head 30 (sucking nozzles 31) with respect to the mounting apparatus 100 and a movement distance of the mounting head 30 in the X- and Y-axis directions. On the other hand, in this embodiment, the cycle T by which the acceleration becomes 0 is calculated at each timing at which the sucking nozzle 31 mounts the electronic component. Therefore, an appropriate measure can be taken even when the cycle T varies depending on the parameters described above.

### Second Embodiment

Next, a second embodiment of the present disclosure will be described. In the descriptions on the second and subsequent embodiments, descriptions on parts having the same structures and functions as those of the first embodiment above will be omitted or simplified.

In the first embodiment above, the case where the cycle T by which the acceleration becomes 0 is measured at each timing at which the sucking nozzle 31 moves toward the substrate 1 has been described. On the other hand, the second embodiment is different from the first embodiment in that the cycle T by which the acceleration becomes 0 is measured in advance before the electronic component is mounted on the substrate 1 by the sucking nozzle 31 based on the acceleration information.

In the second embodiment, the cycle T by which the acceleration becomes 0 is first measured in advance. As the cycle T by which the acceleration becomes 0 is measured, information on the cycle T is stored in the storage 6 in advance. It should be noted that the cycle T by which the acceleration becomes 0 may vary depending on the parameters such as the position of the mounting head 30 (sucking nozzles 31) with respect to the mounting apparatus 100 and a movement distance of the mounting head 30 as described above. In such a case, the cycle T by which the acceleration becomes 0 is measured for each of the parameters such as the position of the mounting head 30 with respect to the mounting apparatus 100 and a movement distance of the mounting head 30.

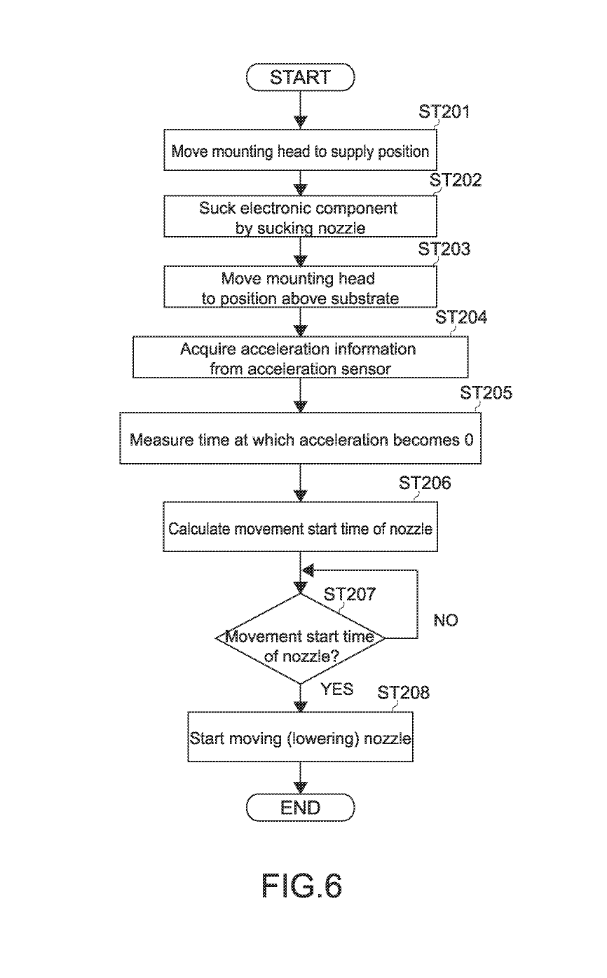

FIG. 6 is a flowchart showing an operation of the mounting apparatus 100 according to the second embodiment.

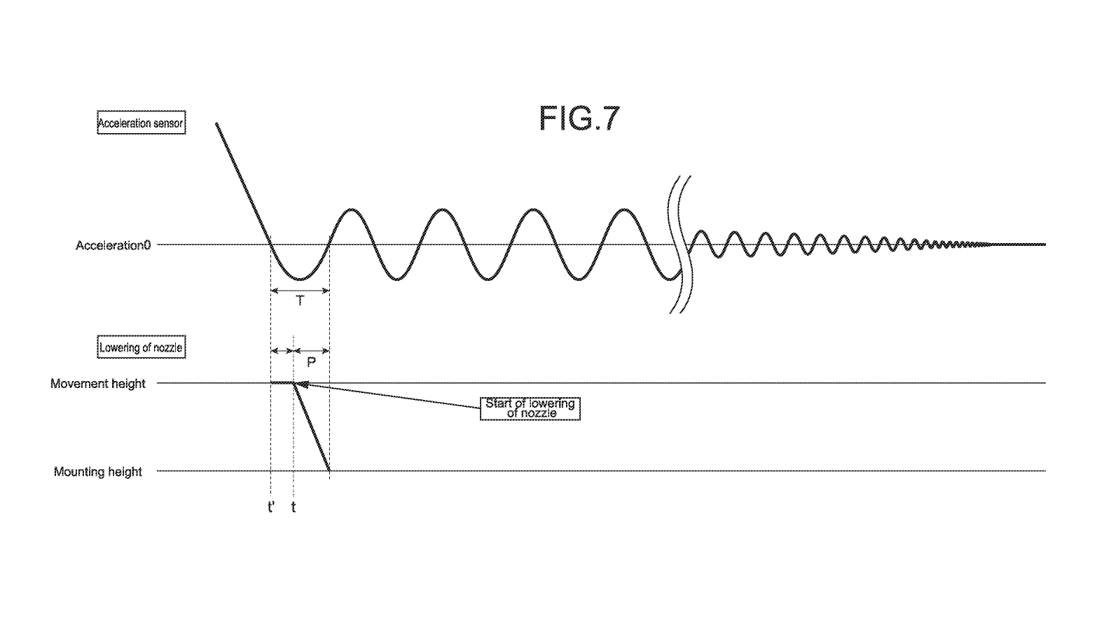

FIG. 7 is a timing chart showing a relationship between an acceleration obtained by the acceleration sensor 50 and a lowering timing of the sucking nozzle 31.

First, the controller 5 moves the mounting head 30 to the electronic component supply position (Step 201) so that the electronic component is sucked by the sucking nozzle 31 (Step 202). Then, the controller 5 moves the mounting head 30 to a position above the substrate 1 and positions the electronic component held by the sucking nozzle 31 at the operation position at the mounting position on the substrate 1 at which the electronic component is to be mounted (Step 203). At this time, the sucking nozzle 31 at the operation position oscillates.

Upon completing the positioning (completion of movement of mounting head 30 in X- and Y-axis directions), the controller 5 next acquires acceleration information from the acceleration sensor 50 (Step 204). Then, the controller 5 measures the time t′ of the timing at which the acceleration becomes 0 after the completion of the positioning (Step 205). It should be noted that in the second embodiment, since the cycle T by which the acceleration becomes 0 is known, the cycle T does not need to be measured at the timing at which the electronic component is mounted. It should be noted that the cycle T may vary for each of the parameters such as the position of the mounting head 30 with respect to the mounting apparatus 100 and a movement distance of the mounting head 30 as described above.

In the example shown in FIG. 7, the time at which the acceleration becomes 0 for the first time after the completion of the positioning is the time t′. By thus setting the time t′ to be the time at which the acceleration becomes 0 for the first time, the speed in mounting the electronic components can be raised. It should be noted that the time t′ is not limited thereto and may be a time at which the acceleration becomes 0 for the second or subsequent times after the completion of the positioning.

Upon measuring the time t′ at which the acceleration becomes 0, the controller 5 next calculates the movement start time t of the sucking nozzle 31 (Step 206). The movement start time t of the sucking nozzle 31 can be obtained by Expression (1) or Expressions (2) and (3) above.

For example, when the cycle T by which the acceleration becomes 0 is about 33 (ms), and the movement time P of the sucking nozzle is 14 (ms), the movement start time t is a time that 19 (ms) has elapsed since the time t′.

Next, the controller 5 judges whether the current time is the movement start time t of the sucking nozzle 31 (Step 207). When the current time is the movement start time t of the sucking nozzle 31 (YES in Step 207), the controller 5 moves the sucking nozzle 31 toward the substrate 1 and mounts the electronic component held by the sucking nozzle 31 on the substrate 1.

Also by the processing as described above, highly-accurate mounting of the electronic components and an improvement of a productivity of the substrate 1 can both be realized. Further, in the second embodiment, the cycle T by which the acceleration becomes 0 is measured in advance. Therefore, a time required from the completion of the positioning to the mounting of the electronic components can be shortened as compared to the case where the cycle T by which the acceleration becomes 0 is measured at each timing at which the sucking nozzle 31 moves toward the substrate 1 (see FIGS. 5 and 7). Consequently, in the second embodiment, the productivity of the substrate 1 can be additionally improved.

When there is still a sucking nozzle 31 holding an electronic component, the controller 5 rotates the turret 32 to switch the sucking nozzle 31 at the operation position. Upon switching the sucking nozzle 31 at the operation position, the controller 5 positions the electronic component held by the sucking nozzle 31 at the operation position at the mounting position on the substrate 1 at which the electronic component is to be mounted.

Also in such a case, the sucking nozzle 31 oscillates. Therefore, also in such a case, the processing of Steps 204 to 208 is executed.

### Various Modified Examples

In the descriptions above, the sensor unit 50 has been provided at a position that oscillates laterally at the same timing as the sucking nozzle 31 at the operation position. However, the sensor unit 50 is not limited thereto and may be located at a position that oscillates at a different timing from the sucking nozzle 31. In this case, as long as a difference between the oscillation timing of the sucking nozzle 31 and that of that position is known, the timing at which the position of the electronic component held by the sucking nozzle 31 overlaps the mounting position on the substrate 1 can be calculated based on a signal from the sensor unit 50.

In the example above, the sucking nozzles 31 have been taken as an example of a holding unit that holds electronic components. However, the holding unit is not limited to the sucking nozzles 31. Another example of the holding unit is a holding unit that sandwiches and holds an electronic component from both sides.

It should be noted that the present disclosure may also take the following structures.

(1) A mounting apparatus, including:

a holding unit configured to hold an electronic component, move toward a substrate while holding the electronic component, and mount the electronic component on the substrate;

a sensor unit configured to detect an oscillation of the holding unit; and

a controller configured to judge, based on information on the oscillation detected by the sensor unit, timings at which a position of the electronic component held by the oscillating holding unit overlaps a mounting position on the substrate, and control a movement of the holding unit toward the substrate such that the electronic component is mounted on the substrate at any of the judged timings.

(2) The mounting apparatus according to (1),

in which the controller calculates a movement start time as a time the holding unit starts moving toward the substrate based on the timings at which the position of the electronic component held by the oscillating holding unit overlaps the mounting position on the substrate and a movement time as a time up to a time the holding unit mounts the electronic component on the substrate since starting to move toward the substrate.

(3) The mounting apparatus according to (2),

in which the controller measures, based on the information on the oscillation, a cycle of the timings at which the position of the electronic component held by the oscillating holding unit overlaps the mounting position on the substrate, and predicts the timings at which the position of the electronic component held by the oscillating holding unit overlaps the mounting position on the substrate based on the measured cycle.

(4) The mounting apparatus according to (3),

in which the controller predicts a timing at which the position of the electronic component held by the oscillating holding unit overlaps the mounting position on the substrate by adding the cycle to a time of any of the timings at which the position of the electronic component held by the oscillating holding unit overlaps the mounting position on the substrate, and calculates a time obtained by subtracting the movement time from the predicted time as the movement start time.

(5) The mounting apparatus according to (4),

in which the controller predicts, by obtaining n using the following expression and adding n times the cycle to a time of any of the timings at which the position of the electronic component held by the oscillating holding unit overlaps the mounting position on the substrate, the timing at which the position of the electronic component held by the oscillating holding unit overlaps the mounting position on the substrate, and calculates a time obtained by subtracting the movement time from the predicted time as the movement start time.

n−1T<P≦nT

(where T represents the cycle, P represents the movement time, and n represents an integer of 1 or more)
(6) The mounting apparatus according to any one of (3) to (5),

in which the controller measures the cycle based on the information on the oscillation for each of timings at which the holding unit moves toward the substrate and mounts the electronic component.

(7) The mounting apparatus according to any one of (3) to (5), further including

a storage,

in which the controller measures, before the holding unit mounts the electronic component, the cycle based on the information on the oscillation and stores the measured cycle in the storage in advance.

(8) The mounting apparatus according to any one of (1) to (7),

in which the sensor unit includes a first sensor that detects an oscillation in a first direction as a direction orthogonal to a direction in which the holding unit moves toward the substrate.

(9) The mounting apparatus according to (8),

in which the sensor unit further includes a second sensor that detects an oscillation in a second direction that is orthogonal to a direction in which the holding unit moves toward the substrate and is different from the first direction.

(10) An electronic component mounting method, including:

detecting an oscillation of a holding unit that holds an electronic component, moves toward a substrate while holding the electronic component, and mounts the electronic component on the substrate;

judging, based on information on the detected oscillation, timings at which a position of the electronic component held by the oscillating holding unit overlaps a mounting position on the substrate; and

controlling a movement of the holding unit toward the substrate such that the electronic component is mounted on the substrate at any of the judged timings, to mount the electronic component on the substrate.

(11) A substrate production method, including:

detecting an oscillation of a holding unit that holds an electronic component, moves toward a substrate while holding the electronic component, and mounts the electronic component on the substrate;

judging, based on information on the detected oscillation, timings at which a position of the electronic component held by the oscillating holding unit overlaps a mounting position on the substrate; and

controlling a movement of the holding unit toward the substrate such that the electronic component is mounted on the substrate at any of the judged timings, to produce the substrate on which the electronic component is mounted.

(12) A program that causes a mounting apparatus to execute the steps of:

detecting an oscillation of a holding unit that holds an electronic component, moves toward a substrate while holding the electronic component, and mounts the electronic component on the substrate;

judging, based on information on the detected oscillation, timings at which a position of the electronic component held by the oscillating holding unit overlaps a mounting position on the substrate; and

controlling a movement of the holding unit toward the substrate such that the electronic component is mounted on the substrate at any of the judged timings.

The present disclosure contains subject matter related to that disclosed in Japanese Priority Patent Application JP 2011-210935 filed in the Japan Patent Office on Sep. 27, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A mounting apparatus, comprising:
a holding unit configured to hold an electronic component, move toward a substrate while holding the electronic component, and mount the electronic component on the substrate;
a sensor unit configured to detect an oscillation of the holding unit; and
a controller configured to judge, based on information on the oscillation detected by the sensor unit, timings at which a position of the electronic component held by the oscillating holding unit overlaps a mounting position on the substrate, and control a movement of the holding unit toward the substrate such that the electronic component is mounted on the substrate at any of the judged timings.

2. The mounting apparatus according to claim 1,
wherein the controller calculates a movement start time as a time the holding unit starts moving toward the substrate based on the timings at which the position of the electronic component held by the oscillating holding unit overlaps the mounting position on the substrate and a movement time as a time up to a time the holding unit mounts the electronic component on the substrate since starting to move toward the substrate.

3. The mounting apparatus according to claim 2,
wherein the controller measures, based on the information on the oscillation, a cycle of the timings at which the position of the electronic component held by the oscillating holding unit overlaps the mounting position on the substrate, and predicts the timings at which the position of the electronic component held by the oscillating holding unit overlaps the mounting position on the substrate based on the measured cycle.

4. The mounting apparatus according to claim 3,
wherein the controller predicts a timing at which the position of the electronic component held by the oscillating holding unit overlaps the mounting position on the substrate by adding the cycle to a time of any of the timings at which the position of the electronic component held by the oscillating holding unit overlaps the mounting position on the substrate, and calculates a time obtained by subtracting the movement time from the predicted time as the movement start time.

5. The mounting apparatus according to claim 4,
wherein the controller predicts, by obtaining n using the following expression and adding n times the cycle to a time of any of the timings at which the position of the electronic component held by the oscillating holding unit overlaps the mounting position on the substrate, the timing at which the position of the electronic component held by the oscillating holding unit overlaps the mounting position on the substrate, and calculates a time obtained by subtracting the movement time from the predicted time as the movement start time.
n−1T<P≦nT
(where T represents the cycle, P represents the movement time, and n represents an integer of 1 or more)

6. The mounting apparatus according to claim 3,
wherein the controller measures the cycle based on the information on the oscillation for each of timings at which the holding unit moves toward the substrate and mounts the electronic component.

7. The mounting apparatus according to claim 3, further comprising
a storage,
wherein the controller measures, before the holding unit mounts the electronic component, the cycle based on the information on the oscillation and stores the measured cycle in the storage in advance.

8. The mounting apparatus according to claim 1,
wherein the sensor unit includes a first sensor that detects an oscillation in a first direction as a direction orthogonal to a direction in which the holding unit moves toward the substrate.

9. The mounting apparatus according to claim 8,
wherein the sensor unit further includes a second sensor that detects an oscillation in a second direction that is orthogonal to a direction in which the holding unit moves toward the substrate and is different from the first direction.

10. An electronic component mounting method, comprising:
detecting an oscillation of a holding unit that holds an electronic component, moves toward a substrate while holding the electronic component, and mounts the electronic component on the substrate;
judging, based on information on the detected oscillation, timings at which a position of the electronic component held by the oscillating holding unit overlaps a mounting position on the substrate; and
controlling a movement of the holding unit toward the substrate such that the electronic component is mounted on the substrate at any of the judged timings, to mount the electronic component on the substrate.

11. A substrate production method, comprising:
detecting an oscillation of a holding unit that holds an electronic component, moves toward a substrate while holding the electronic component, and mounts the electronic component on the substrate;
judging, based on information on the detected oscillation, timings at which a position of the electronic component held by the oscillating holding unit overlaps a mounting position on the substrate; and
controlling a movement of the holding unit toward the substrate such that the electronic component is mounted on the substrate at any of the judged timings, to produce the substrate on which the electronic component is mounted.

12. A program that causes a mounting apparatus to execute the steps of:
detecting an oscillation of a holding unit that holds an electronic component, moves toward a substrate while holding the electronic component, and mounts the electronic component on the substrate;
judging, based on information on the detected oscillation, timings at which a position of the electronic component held by the oscillating holding unit overlaps a mounting position on the substrate; and
controlling a movement of the holding unit toward the substrate such that the electronic component is mounted on the substrate at any of the judged timings.
